(19) United States
(12) Patent Application Publication
(10) Pub. No.: US 2022/0262979 A1
(43) Pub. Date: Aug. 18, 2022

(54) OPTOELECTRONIC SEMICONDUCTOR CHIP AND METHOD FOR PRODUCING AN OPTOELECTRONIC SEMICONDUCTOR CHIP

(71) Applicant: OSRAM Opto Semiconductors GmbH, Regensburg (DE)

(72) Inventor: Siegfried HERRMANN, Neukirchen (DE)

(21) Appl. No.: 17/628,912

(22) PCT Filed: Jul. 17, 2020
(86) PCT No.: PCT/EP2020/070321

§ 371 Date: Jan. 21, 2022

(30) Foreign Application Priority Data
Jul. 23, 2019 (DE) 10 2019 119 891.7

(51) Int. Cl. H01L 33/08; H01L 25/075; H01L 33/38; H01L 33/62; H01L 33/00

(52) U.S. Cl. CPC H01L 33/08; H01L 25/0756; H01L 33/382; H01L 24/32; H01L 33/0075; H01L 2933/0016; H01L 2933/0066; H01L 33/62

(57) ABSTRACT

The optoelectronic semiconductor chip may include a composite having a front face, a first semiconductor layer sequence and a second semiconductor layer sequence between the front face and the first semiconductor layer sequence, a first and a second contact element on a side of the composite opposite the front face, and a first and a second through-connection. The first and second semiconductor layer sequences each include an active layer for generating or absorbing electromagnetic radiation. The first contact element and the first through-connection are configured to electrically contact the first semiconductor layer sequence, and the second contact element and the second through-connection are configured to electrically contact the second semiconductor layer sequence. The first through-connection is guided through the active layer of the first semiconductor layer sequence and the second through-connection is guided through the active layer of the second semiconductor layer sequence.

### CROSS-REFERENCE TO RELATED APPLICATIONS

The present application is a national stage entry according to 35 U.S.C. § 371 of PCT application No.: PCT/EP2020/070321 filed on Jul. 17, 2020; which claims priority to German Patent Application Serial No.: 10 2019 119 891.7 filed on Jul. 23, 2019; all of which are incorporated herein by reference in their entirety and for all purposes.

### TECHNICAL FIELD

The specification relates to an optoelectronic semiconductor chip and a method for producing an optoelectronic semiconductor chip.

### BACKGROUND

One object to be achieved is to specify a high-luminance optoelectronic semiconductor chip. Another object to be achieved is to specify a method for producing such a semiconductor chip.

### SUMMARY

First, the optoelectronic semiconductor chip is specified. In particular, the optoelectronic semiconductor chip is an LED chip for emitting electromagnetic radiation in the UV range or in the visible range or in the infrared range. In particular, the semiconductor chip is intended for use in a headlamp, for example in a projection headlamp or in a car headlamp. The semiconductor chip may further be used in lamps for interior or exterior lighting, or as a flash light or display light in a mobile phone.

A semiconductor chip is understood here and in the following to be a separately manageable and electrically contactable element. A semiconductor chip is created in particular by cutting a wafer composite. In particular, side surfaces of a semiconductor chip then exhibit, for example, traces from the separation process of the wafer composite.

According to at least one embodiment, the optoelectronic semiconductor chip comprises a composite having a front face, a first semiconductor layer sequence and a second semiconductor layer sequence. The second semiconductor layer sequence is arranged between the front face and the first semiconductor layer sequence.

In particular, the front face is a top surface of the composite. The front face is, for example, a radiation exit surface of the composite or of the semiconductor chip. In the intended operation of the semiconductor chip, at least 50% or at least 75% of the radiation generated in the semiconductor chip is coupled out via the front face, for example. The front face may be formed by the second semiconductor layer sequence.

For example, the semiconductor layer sequences are each based on a III-V compound semiconductor material. The semiconductor material is, for example, a nitride compound semiconductor material, such as AlₙIn₁₋ₙ₋ₘGaₘN, or a phosphide compound semiconductor material, such as AlₙIn₁₋ₙ₋ₘGaₘP, or an arsenide compound semiconductor material, such as AlₙIn₁₋ₙ₋ₘGaₘAs or AlₙIn₁₋ₙ₋ₘGaₘAsP, with 0≤n≤1, 0≤m≤1, and m+n 1, respectively. Here, the semiconductor layer sequences may comprise dopants as well as additional components. However, for the sake of simplicity, only the essential constituents of the crystal lattice of the semiconductor layer sequence, i.e. Al, As, Ga, In, N or P, are indicated, even if these may in some cases be replaced and/or supplemented by small amounts of further substances. In a non-limiting embodiment, the semiconductor layer sequences are each based on AlInGaN.

The first semiconductor layer sequence can be directly adjacent to the second semiconductor layer sequence, or a connection layer, in particular an electrically insulating connection layer, can be arranged between the first semiconductor layer sequence and the second semiconductor layer sequence. The connection layer comprises, for example, SiO₂ or SiN or silicone. The first semiconductor layer sequence and the second semiconductor layer sequence may be electrically insulated from each other. This means that no current flow takes place between two facing sides of the two semiconductor layer sequences during intended operation.

According to at least one embodiment, the optoelectronic semiconductor chip comprises a first contact element and a second contact element on a side of the composite opposite the front face. The two contact elements are electrically conductive, in particular metallic. For example, the first and second contact elements each comprise one or more of the following materials: Al, Ag, Au, Cu, Ni, Ti, Cr.

According to at least one embodiment, the optoelectronic semiconductor chip comprises a first through-connection and a second through-connection, each extending into the composite from the side of the composite opposite the front face. The through-connections are electrically conductive. They comprise, for example, a metal, for example one of the metals mentioned in the last paragraph. The through-connections extend into the composite without completely penetrating the composite. This means that the through-connections terminate within the composite.

According to at least one embodiment, the first and the second semiconductor layer sequence each comprise an active layer. The active layers are each configured to generate or absorb electromagnetic radiation. The active layers of the two semiconductor layer sequences are different from each other and arranged spaced apart from each other in a direction perpendicular to the front face.

In a non-limiting embodiment, the first and second semiconductor layer sequences further comprise respective first and second layers of semiconductor material between which the associated active layer is arranged. The first and second layers may each have a multilayer structure. For example, the first layers of both semiconductor layer sequences are n-doped and the second layers are p-doped or vice versa. The two semiconductor layer sequences may be arranged on top of each other such that the second layer of the first semiconductor layer sequence and the first layer of the second semiconductor layer sequence face each other.

The active layers of the two semiconductor layer sequences extend in particular parallel or substantially parallel to one another. The lateral extent of the semiconductor chip, measured along the front face or along a main extension plane of the front face, is, for example, at most 20% or at most 10% or at most 5% greater than the lateral extent of the second semiconductor layer sequence or its active layer.

The active layers of the semiconductor layer sequences each include at least one pn junction and/or at least one quantum well structure in the form of a single quantum well, SQW for short, or in the form of a multi quantum well structure, MQW for short. In the intended operation, the active layers each generate, for example, electromagnetic radiation in the blue or green or red spectral range or in the UV range or in the IR range.

For example, on a side facing the composite, the contact elements are each made of a material which is reflective for the radiation generated by the active layers. Alternatively or additionally, a dielectric mirror is arranged between the contact elements and the composite, an electrical connection from the contact elements to the composite then being formed, for example, via contact pins through the dielectric mirror.

According to at least one embodiment, the first contact element and the first through-connection are arranged for electrically contacting the first semiconductor layer sequence. The second contact element and the second through-connection are arranged for electrically contacting the second semiconductor layer sequence.

In the intended operation of the semiconductor chip, the first contact element and the first through-connection are at different potentials. For example, the first contact element is electrically connected to the first layer of the first semiconductor layer sequence and the first through-connection is electrically connected to the second layer of the first semiconductor layer sequence. The first contact element and the first through-connection may be directly adjacent to the respective layers of the first semiconductor layer sequence. What has just been disclosed applies mutatis mutandis to the second contact element and the second through-connection.

The contact elements and through-connections are arranged in particular such that the first semiconductor layer sequence and the second semiconductor layer sequence can be contacted in parallel, i.e. can be electrically connected in parallel with one another. This means that, during operation, charge carriers can flow simultaneously through both semiconductor layer sequences, wherein charge carriers flowing through the first semiconductor layer sequence do not enter the second semiconductor layer sequence and vice versa.

According to at least one embodiment, the first through-connection is guided through the active layer of the first semiconductor layer sequence and the second through-connection is guided through the active layer of the second semiconductor layer sequence. For example, for this purpose the second through-connection is also guided through the first semiconductor layer sequence, so that the second through-connection is laterally partly or completely surrounded by the first semiconductor layer sequence in the region of the first semiconductor layer sequence. “Laterally” means here and in the following in the lateral direction, i.e. in the direction parallel to the front face or main extension plane of the front face.

Thus, the first through-connection penetrates the first layer and the active layer of the first semiconductor layer sequence and terminates in the second layer of the first semiconductor layer sequence. The second through-connection penetrates the first layer and the active layer of the second semiconductor layer sequence and terminates in the second layer of the second semiconductor layer sequence. In particular, the first and the second through-connection thus terminate at different distances from the front face.

Advantageously, the first through-connection is electrically insulated from the first semiconductor layer sequence in the region of the first layer and the active layer of the first semiconductor layer sequence. In a non-limiting embodiment, the first through-connection is laterally completely surrounded by the active layer of the first semiconductor layer sequence. In a non-limiting embodiment, the first through-connection does not protrude into the second semiconductor layer sequence.

Advantageously, the second through-connection is electrically insulated from the first semiconductor layer sequence in the region of the first semiconductor layer sequence. In the region of the first layer and the active layer of the second semiconductor layer sequence, the second through-connection may be electrically insulated from the second semiconductor layer sequence. The second through-connection may be laterally completely surrounded by the active layer of the second semiconductor layer sequence.

In at least one embodiment, the optoelectronic semiconductor chip comprises a composite having a front face, a first semiconductor layer sequence and a second semiconductor layer sequence between the front face and the first semiconductor layer sequence. The semiconductor chip comprises a first contact element and a second contact element on a side of the composite opposite the front face, and a first through-connection and a second through-connection each extending into the composite from the side of the composite opposite the front face. The first and the second semiconductor layer sequence each include an active layer for generating or absorbing electromagnetic radiation. The first contact element and the first through-connection are arranged for electrically contacting the first semiconductor layer sequence, and the second contact element and the second through-connection are arranged for electrically contacting the second semiconductor layer sequence. The first through-connection is guided through the active layer of the first semiconductor layer sequence and the second through-connection is guided through the active layer of the second semiconductor layer sequence.

Advantageously, the structure of the semiconductor chip described here with two semiconductor layer sequences, each comprising an active layer, and contacting of the semiconductor layer sequences in each case with the aid of a through-connection results in an increase in the area active during operation with a relatively small radiation area (area of the front face). Thus, a high luminance is achieved. In contrast to the use of contact elements both on the front face and on the side opposite the front face, power dissipation can be reduced with the structure described here since a transition region in the form of a tunnel barrier can be dispensed with.

According to at least one embodiment, the second contact element is guided through the first semiconductor layer sequence up to the second semiconductor layer sequence. The second contact element thus extends from the side of the composite opposite the front face into the composite and extends as far as the second semiconductor layer sequence. In the region of the first semiconductor layer sequence, the second contact element is partly or completely surrounded by the first semiconductor layer sequence. However, the second contact element does not penetrate the active layer of the second semiconductor layer sequence. In a non-limiting embodiment, the second contact element is adjacent to the first layer of the second semiconductor layer sequence and is in direct electrical contact with this layer.

According to at least one embodiment, the first and the second contact element are electrically connected to each other and are at the same potential in the intended operation. For example, the first contact element and the second contact element are formed contiguously, in particular integrally, with one another.

According to at least one embodiment, the first and the second through-connection are electrically conductively connected to one another and are at the same potential in the intended operation. The first through-connection and the second through-connection are in particular formed contiguously, for example integrally, with one another.

According to at least one embodiment, the first and the second contact element can be electrically contacted independently of each other. Alternatively or additionally, the first and the second through-connection can be electrically contacted independently of each other. As a result, in particular the first and the second semiconductor layer sequence can be contacted or operated independently of each other. Thus, radiation can be generated or absorbed in the active layer of the first semiconductor layer sequence while the active layer of the second semiconductor layer sequence is out of operation and vice versa.

According to at least one embodiment, the active layers of the first and second semiconductor layer sequences are configured to emit radiation of different wavelengths. For example, a global intensity maximum of the radiation generated by the active layer of the first semiconductor layer sequence is at a different wavelength, for example at a wavelength shifted by at least 20 nm or at least 50 nm, than a global intensity maximum of the radiation emitted by the active layer of the second semiconductor layer sequence.

According to at least one embodiment, the second through-connection is guided through the second contact element and is electrically insulated from the second contact element. In particular in the region of the first semiconductor layer sequence, the second through-connection may be completely surrounded laterally by the second contact element.

According to at least one embodiment, the second semiconductor layer sequence is formed contiguously. In particular, the active layer of the second semiconductor layer sequence is contiguous. In the region of the second through-connection, the active layer is interrupted by the second through-connection.

According to at least one embodiment, the first semiconductor layer sequence comprises a plurality of laterally spaced semiconductor blocks. In other words, the first semiconductor layer sequence is not formed contiguously but is divided into a plurality of non-contiguous semiconductor blocks. The semiconductor blocks are distributed along the second semiconductor layer sequence. For example, the semiconductor blocks of the first semiconductor layer sequence are arranged at regular intervals from each other on the second semiconductor layer sequence. For example, the semiconductor blocks are arranged in a rectangular pattern on the second semiconductor layer sequence. For example, the first semiconductor layer sequence comprises at least 10 or at least 100 or at least 10000 such semiconductor blocks.

Each semiconductor block includes an active layer. The active layer of a semiconductor block may be formed contiguously in each case. The active layers of different semiconductor blocks are separated from each other and are not connected.

For example, the semiconductor blocks of the first semiconductor layer sequence each have a square base area. In particular, lateral extents of the semiconductor blocks may each be between 5 μm and 500 μm, inclusive. In a non-limiting embodiment, lateral extents of the semiconductor blocks are each in the range between 10 μm and 200 μm, inclusive, or between 10 μm and 100 μm, inclusive.

According to at least one embodiment, the second contact element extends in the region between the semiconductor blocks up to the second semiconductor layer sequence. For example, the second contact element forms a frame, in particular a contiguous and closed frame, in the lateral direction around at least one or around each of the semiconductor blocks. As viewed in a cross-sectional view in a section along the first semiconductor layer sequence, the second contact element may form a grid, wherein the semiconductor blocks lie in the meshes of the grid and each mesh has a semiconductor block uniquely associated therewith. The second through-connections may extend in the region of the intersections of the grid lines.

According to at least one embodiment, the semiconductor chip comprises a plurality of the first and/or second through-connections. For example, the semiconductor chip comprises at least 10 or at least 100 or at least 10000 of the first and/or second through-connections. All features disclosed for the first and the second through-connection are also disclosed for all further first and second through-connections.

In a non-limiting embodiment, the first through-connections are all electrically connected to each other and can only be operated together. Likewise, the second through-connections may be all electrically connected to each other and can only be operated together.

Alternatively, the first through-connections may be individually and independently contactable. For example, the first semiconductor layer sequence is divided into a plurality of emission fields or pixels, each first through-connection being uniquely or biuniquely associated with a pixel. For example, first through-connections associated with different pixels of the first semiconductor layer sequence may be contacted individually and independently of each other, such that the individual pixels of the first semiconductor layer sequence are individually and independently operable. The semiconductor blocks may form the pixels of the first semiconductor layer sequence. For example, the semiconductor blocks can be controlled individually and independently.

Similarly, the second through-connections may be individually and independently contactable. For example, the second semiconductor layer sequence is divided into a plurality of emission fields or pixels, each second through-connection being uniquely or biuniquely associated with a pixel. For example, second through-connections associated with different pixels of the second semiconductor layer sequence may be contacted individually and independently of each other, such that the individual pixels of the second semiconductor layer sequence are individually and independently operable.

Thus, the optoelectronic semiconductor chip may be, in particular, a pixelated optoelectronic semiconductor chip, which may be advantageous, for example, when used in a car headlight.

According to at least one embodiment, each semiconductor block of the first semiconductor layer sequence is uniquely, or biuniquely, associated with at least one first through-connection. The associated first through-connection may extend through the semiconductor block and is laterally completely surrounded by the semiconductor material of the semiconductor block.

According to at least one embodiment, the first semiconductor layer sequence is formed contiguously. In particular, the active layer of the first semiconductor layer sequence is formed contiguously. In the region of the first through-connections, the active layer of the first semiconductor layer sequence is interrupted by the first through-connections.

According to at least one embodiment, the first and second semiconductor layer sequences, or also the respectively associated active layers, each extend over at least 80% or at least 90% of the lateral extent of the semiconductor chip.

According to at least one embodiment, the first semiconductor layer sequence has a thickness between 1 μm and 5 μm, inclusive, such as between 1.5 μm and 2.5 μm, inclusive. For example, the second semiconductor layer sequence has a thickness between 3 μm and 10 μm, inclusive, such as between 4 μm and 6 μm, inclusive. The thickness is measured perpendicular to the front face or perpendicular to the main extension plane of the front face. Thickness is understood here and hereinafter to be the maximum or average or minimum thickness.

According to at least one embodiment, the optoelectronic semiconductor chip comprises a carrier on a side of the composite opposite the front face. The carrier is formed, for example, from an electrically insulating material, such as a plastic. The carrier may be an active or passive matrix element. The carrier stabilizes the composite.

According to at least one embodiment, the second contact element comprises a mirror, for example a metallic mirror or a Bragg mirror, on a side facing the second semiconductor layer sequence. The mirror is reflective for the radiation generated by the active layer of the second semiconductor layer sequence.

Next, the method for producing an optoelectronic semiconductor chip is specified. In particular, the method can be used to produce an optoelectronic semiconductor chip described herein. All features disclosed in connection with the optoelectronic semiconductor chip are therefore also disclosed for the method, and vice versa.

According to at least one embodiment, the method comprises a step A) of forming a composite comprising a first semiconductor layer sequence including an active layer and a second semiconductor layer sequence including an active layer. The composite comprises a front face. The second semiconductor layer sequence is arranged between the front face and the first semiconductor layer sequence.

In a step B1) of the method, a first contact element is formed. In a step B2) of the method, a first through-connection is formed. In this process, the first through-connection is guided through the active layer of the first semiconductor layer sequence. The first contact element and the first through-connection are arranged for electrically contacting the first semiconductor layer sequence.

In a step C1) of the method, a second contact element is formed on a side of the composite opposite the front face. In a step C2) of the method, a second through-connection is formed, the second contact element and the second through-connection being arranged for electrically contacting the second semiconductor layer sequence. The second through-connection is guided through the active layer of the second semiconductor layer sequence.

Steps B1), B2), C1) and C2) can be carried out after step A). Steps B1) and C1) are then carried out together, for example, so it is one method step. Similarly, steps B2) and C2) can also be carried out together.

Alternatively, steps B1) and B2) are carried out before step A). Then, after step A), steps C1) and C2) are carried out.

According to at least one embodiment, a plurality of semiconductor blocks each having an active layer is provided in step A). The semiconductor blocks are deposited as separate elements spaced apart from each other on the second semiconductor layer sequence and together form the first semiconductor layer sequence. A distance between each two adjacent semiconductor blocks is, for example, at least 2 μm and/or at most 100 μm.

According to at least one embodiment, step B2) is carried out before step A). In particular, the semiconductor blocks are provided with first through-connections before being deposited on the second semiconductor layer sequence. Similarly, step B1) may be carried out before step A). This means that the semiconductor blocks are then each provided with a first contact element before the semiconductor blocks are deposited on the second semiconductor layer sequence. In particular, the semiconductor blocks are provided in the form of functional micro-LED chips. The micro-LED chips can also be operated without the second semiconductor layer sequence and emit electromagnetic radiation during operation.

According to at least one embodiment, in step A), the first semiconductor layer sequence is deposited as a contiguous semiconductor layer sequence on the second semiconductor layer sequence.

According to at least one embodiment, after step A), the first semiconductor layer sequence, in particular the contiguous first semiconductor layer sequence, is segmented into a plurality of semiconductor blocks. For this purpose, a mask and an etching process are used, for example.

According to at least one embodiment, in step A) the first semiconductor layer sequence and the second semiconductor layer sequence are fixed on top of each other by bonding. In particular, a wafer-to-wafer bonding method is used. For example, a direct bonding method or a thermocompression bonding method is used. In particular, the individual semiconductor blocks or micro-LED chips are attached to the second semiconductor layer sequence by bonding.

According to at least one embodiment, in step A) the second semiconductor layer sequence and the first semiconductor layer sequence or the individual semiconductor blocks are glued on top of each other. A connection layer, for example in the form of an adhesive layer, is then present between the first semiconductor layer sequence and the second semiconductor layer sequence. The connection layer has, for example, a thickness of at most 200 nm or at most 100 nm. The connection layer is based, for example, on a silicone. The connection layer is in particular electrically insulating.

According to at least one embodiment, in step A), the first semiconductor layer sequence and the second semiconductor layer sequence are epitaxially grown on top of each other. For example, an electrically insulating connection layer of a semiconductor material is then grown between the first semiconductor layer sequence and the second semiconductor layer sequence. The connection layer is then nominally undoped, for example.

Further advantageous embodiments and further developments of the optoelectronic semiconductor chip and of the method for producing an optoelectronic semiconductor chip will become apparent from the exemplary embodiments described below in connection with the figures. Identical elements, elements of the same kind or elements having the same effect are provided with the same reference signs in the figures. The figures and the proportions of the elements shown in the figures with respect to one another are not to be regarded as true to scale. Rather, individual elements, in particular layer thicknesses, may be shown exaggeratedly large for better representability and/or for better understanding.

### BRIEF DESCRIPTION OF THE DRAWINGS

In the figures:

FIGS. 1A to 1C show various views of a first exemplary embodiment of the optoelectronic semiconductor chip,

FIGS. 2 to 4 show cross-sectional views of further exemplary embodiments of the optoelectronic semiconductor chip,

FIGS. 5A and 5B show another exemplary embodiment of the optoelectronic semiconductor chip in various views,

FIGS. 6A to 7E show various positions in two exemplary embodiments of the method for producing an optoelectronic semiconductor chip.

In the detailed description that follows, reference will be made to the attached drawings, which form part of this description and in which specific exemplary embodiments may be realized are shown for illustration purposes. Because components of exemplary embodiments can be positioned in a number of different orientations, the directional terminology is used for illustration purposes only, and is in no way restrictive. It goes without saying that other exemplary embodiments can be used and structural or logical changes can be made without departing from the scope of protection. It goes without saying that the features of the various exemplary embodiments described herein can be combined with one another, unless specifically stated otherwise. The following detailed description is therefore not to be interpreted in a restrictive sense. In the figures, identical or similar elements are labeled with identical reference numerals, where this is appropriate.

### DETAILED DESCRIPTION

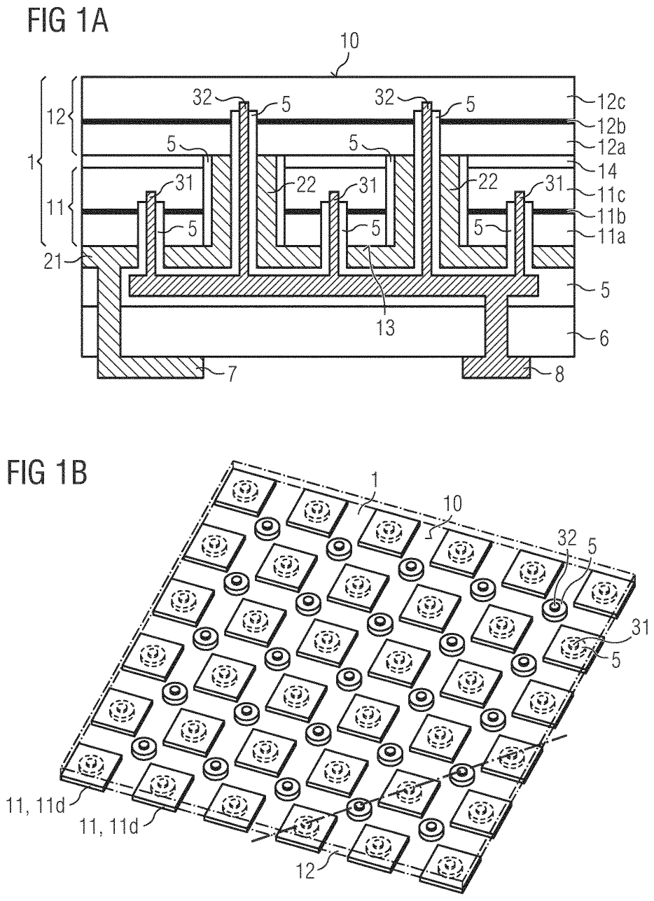

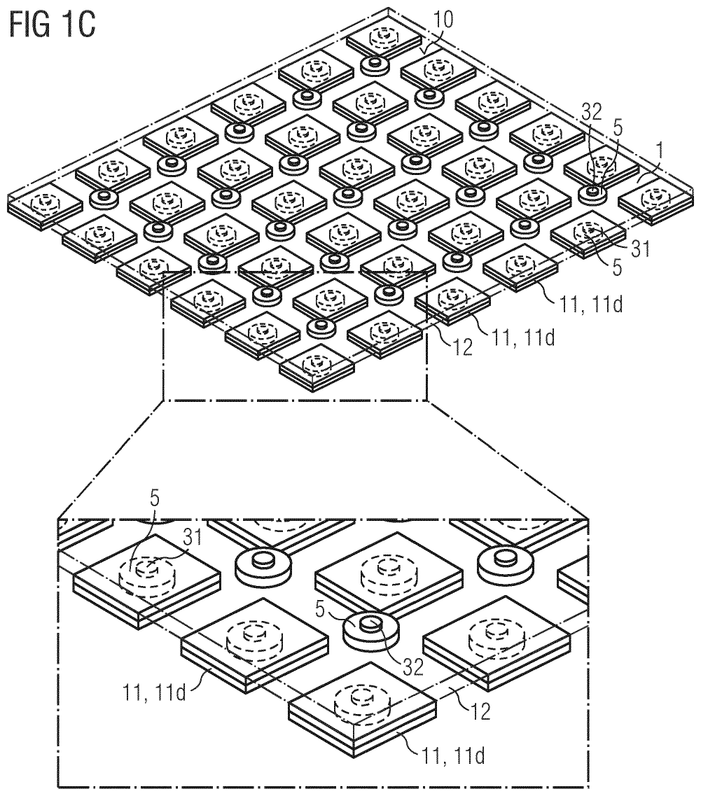

FIG. 1A shows a first exemplary embodiment of the optoelectronic semiconductor chip in a cross-sectional view. The semiconductor chip is, for example, an LED chip. The optoelectronic semiconductor chip comprises a composite 1 having a front face 10 and a rear face 13 opposite the front face 10. In particular, the front face 10 forms a radiation exit surface of the semiconductor chip, via which a large part of the generated radiation is coupled out during intended operation of the semiconductor chip.

The composite 1 comprises a first semiconductor layer sequence 11 and a second semiconductor layer sequence 12, the first semiconductor layer sequence 11 being arranged downstream of the second semiconductor layer sequence 12 in the direction away from the front face 10. Between the first semiconductor layer sequence 11 and the second semiconductor layer sequence 12, a connection layer 14 is provided which mechanically connects the two semiconductor layer sequences 11, 12 to each other. The connection layer 14 may be electrically insulating. In the present case, the connection layer 14 is, for example, an adhesive layer, for example made of a silicone adhesive.

The first semiconductor layer sequence 11 comprises a first layer 11a of semiconductor material, a second layer 11c of semiconductor material, and an active layer 11b between the first layer 11a and the second layer 11c. The second semiconductor layer sequence 12 comprises a first layer 12a of semiconductor material, a second layer 12 of semiconductor material, and an active layer 12b therebetween. The first layers 11a, 12a are doped opposite to the second layers 11c, 12c. For example, the two first layers 11a, 12a are p-doped, and the two second layers 11c, 12c are n-doped, or vice versa.

The optoelectronic semiconductor chip comprises a first contact element 21 and a second contact element 22 at the rear face 13 of the composite 1 opposite the front face 10. In the present case, the two contact elements 21, 22 are formed contiguously, even integrally with each other. For example, the two contact elements 21, 22 are formed of a metal, such as silver.

The first contact element 21 adjoins and contacts the first layer 11a of the first semiconductor layer sequence 11. The second contact element 22 includes regions guided through the first semiconductor layer sequence 11 up to the first layer 12a of the second semiconductor layer sequence 12. In these regions, the second contact element 22 contacts the first layer 12a. The second contact element 22 is electrically insulated from the first semiconductor layer sequence 11 by an insulation material 5 in these regions. The insulation material 5 is, for example, SiO₂ or SiN. The insulation material 5 between the second contact element 22 and the first semiconductor layer sequence 11 may also be a dielectric mirror.

Furthermore, the semiconductor chip comprises first through-connections 31 extending from the rear face 13 into the composite 1. The first through-connections 31 penetrate the first layer 11a as well as the active layer 11b of the first semiconductor layer sequence 11 and terminate in the second layer 11c of the first semiconductor layer sequence 11, where the first through-connections 31 contact the second layer 11c. Thus, the first semiconductor layer sequence 11 is electrically contacted via the first contact element 21 and the first through-connections 31. The first through-connections 31 are insulated from the semiconductor layer sequence 11 by the insulation material 5 in the region of the first layer 11a and the active layer 11b.

In addition, second through-connections 32 are provided in the semiconductor chip, which each extend from the rear face 13 through the first semiconductor layer sequence 11 into the second semiconductor layer sequence 12, completely penetrating the first semiconductor layer sequence 11. The second through-connections 32 further penetrate the first layer 12a and the active layer 12b of the second semiconductor layer sequence 12 and terminate in the second layer 12c of the second semiconductor layer sequence 12. The second through-connections 32 are electrically insulated in the region of the first layer 12a and the active layer 12b of the second semiconductor layer sequence 12 by the insulation material 5.

In FIG. 1A, it can also be seen that the second through-connections 32 are guided through the regions of the second contact element 22, which in turn are guided through the first semiconductor layer sequence 11.

In the present exemplary embodiment, the first through-connections 31 and the second through-connections 32 are electrically conductively connected to each other and are at the same potential in the intended operation of the semiconductor chip. The same applies to the first and second contact elements 21, 22. The first and second through-connections include or consist, for example, of Al.

The semiconductor chip of FIG. 1A comprises a carrier 6, for example a plastic carrier. The carrier 6 supports the composite 1 and stabilizes it. Connection areas 7, 8 are provided on a side of the carrier 6 facing away from the composite 1. One connection area 7 is electrically conductively connected to the first contact element 21 and the second contact element 22. Another connection area 8 is electrically conductively connected to the first and second through-connections 31, 32. In the unassembled state of the semiconductor chip, the connection areas 7, 8 are exposed. The semiconductor chip of FIG. 1A is a surface-mountable semiconductor chip.

In FIG. 1B, the semiconductor chip of FIG. 1A is shown in perspective view. For clarity, the carrier 6 and the first 21 and second 22 contact elements are not shown. FIG. 1A is a sectional view along the dashed-dotted line of FIG. 1B.

In FIG. 1B, it can be seen that the second semiconductor layer sequence 12 is formed contiguously and the first semiconductor layer sequence 11 is formed of a plurality of semiconductor blocks 11d. The semiconductor blocks 11d are arranged along the second semiconductor layer sequence 12 and are spaced apart from each other in pairs. A grid of trenches spaces the semiconductor blocks 11d, with one semiconductor block located in each mesh of the grid. The second contact element 22, which is not shown, extends up to the second semiconductor layer sequence 12 in the region between each two adjacent semiconductor blocks 11d and fills the grid of trenches.

The second through-connections 32 are arranged in the region of the intersections of the grid lines. One of the first through-connections 31 is biuniquely associated with each of the semiconductor blocks 11d, the first through-connections 31 each extending through the associated semiconductor block 11d.

In FIG. 1C, the optoelectronic semiconductor chip of FIG. 1B is again shown without the carrier and the contact elements in a further perspective view. In addition, a section of the semiconductor chip is shown enlarged.

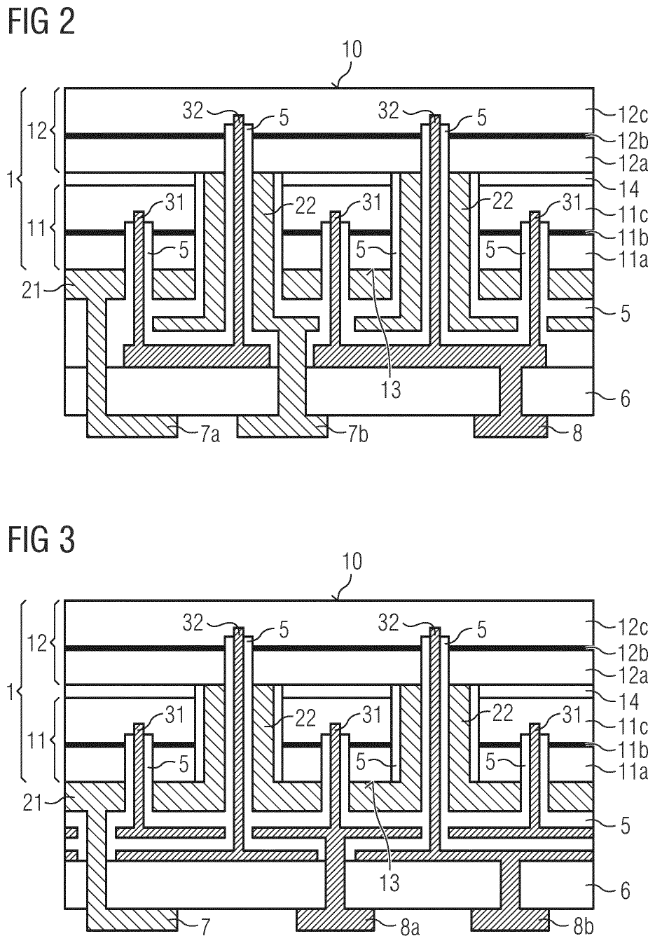

FIG. 2 shows a second exemplary embodiment of the semiconductor chip, again in a cross-sectional view. In contrast to the semiconductor chip of FIG. 1A, here the first contact element 21 and the second contact element 22 can be electrically contacted independently of each other. In particular, the first contact element 21 and the second contact element 22 are not formed contiguously in this case.

The first contact element 21 is electrically conductively connected to a connection area 7a on a rear face of the carrier 6. The second contact element 22 is electrically conductively connected to a connection area 7b, which is different from the connection area 7a, on the rear face of the carrier 6. The two connection areas 7a, 7b can be contacted or supplied with current individually and independently of each other.

FIG. 3 shows a third exemplary embodiment of the semiconductor chip. Unlike in FIG. 2, here it is not the first contact element 21 and the second contact element 22 that can be contacted individually and independently of one another but the first through-connections 31 and the second through-connections 32. The first through-connections 31 are electrically conductively connected to their own connection area 8a on the rear face of the carrier 6, and the second through-connections 32 are electrically conductively connected to their own connection area 8b on the rear face of the carrier 6. The connection areas 8a, 8b can be contacted or supplied with current individually and independently of each other.

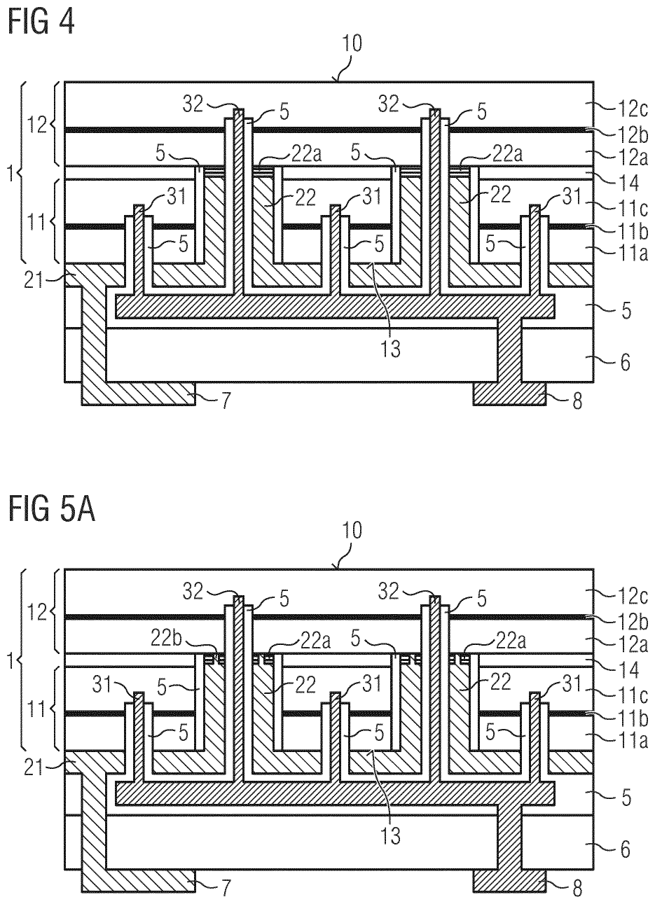

FIG. 4 shows a fourth exemplary embodiment of the optoelectronic semiconductor chip. In contrast to the optoelectronic semiconductor chip of FIG. 1, the second contact element 22 in the region adjacent to the second semiconductor layer sequence 12 is now not formed of metal, but by an electrically conductive Bragg mirror 22a comprising a plurality of transparent layers with different refractive indices. The layers of the mirror 22a contain, for example, different conductive oxides.

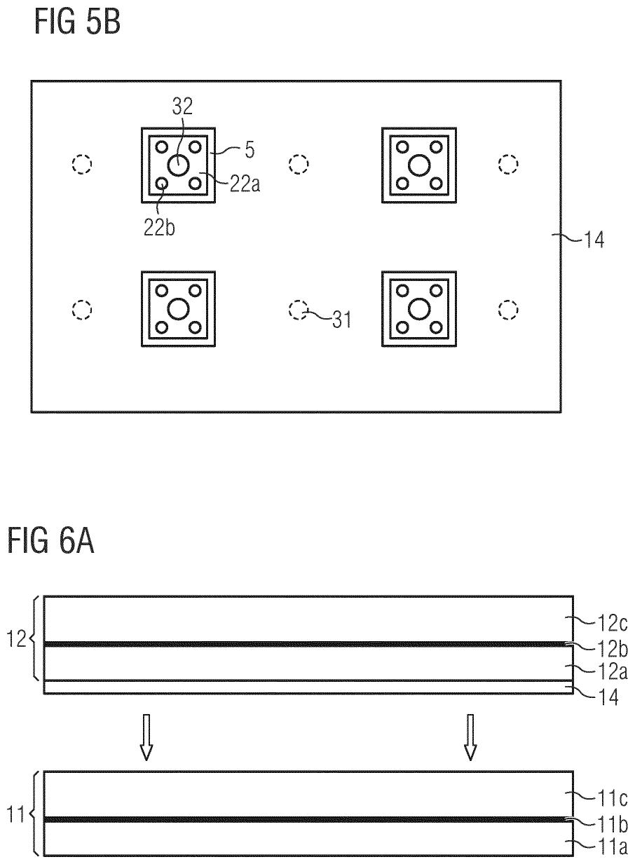

FIG. 5A shows a fifth exemplary embodiment of the optoelectronic semiconductor chip, again in cross-sectional view. In contrast to the exemplary embodiment of FIG. 4, here the Bragg mirror 22a is not made of electrically conductive transparent layers, but of dielectric layers. In order to nevertheless enable contacting to the second semiconductor layer sequence 12, the mirror 22a is interspersed with metallic contact pins 22b which electrically conductively connect the electrically conductive material of the second contact element 22 to the second semiconductor layer sequence 12.

Similarly, a dielectric mirror may be arranged between the first contact element 21 and the first semiconductor layer sequence 11, wherein an electrical connection between the first semiconductor layer sequence 11 and the first contact element 21 is provided by contact pins.

In FIG. 5B, the optoelectronic semiconductor chip of FIG. 5A is shown in a cross-sectional view when cut through and along the connection layer 14. Firstly, it can be seen here that in the present exemplary embodiment, the second contact element 22 does not form a grid around semiconductor blocks of the first semiconductor layer sequence. Rather, the second contact element 22 is guided through the first semiconductor layer sequence 11 in the region of rectangular apertures. For example, the first semiconductor layer sequence 11 is formed contiguously over its entire lateral extent. In the region of the apertures in the first semiconductor layer sequence 11, the second through-connections 32 are also guided through the second contact element 22. The first through-connections 31 are indicated as dashed circles and are arranged in the region outside the apertures. The second contact element 22 includes a dielectric Bragg mirror 22a through which the contact pins 22b extend.

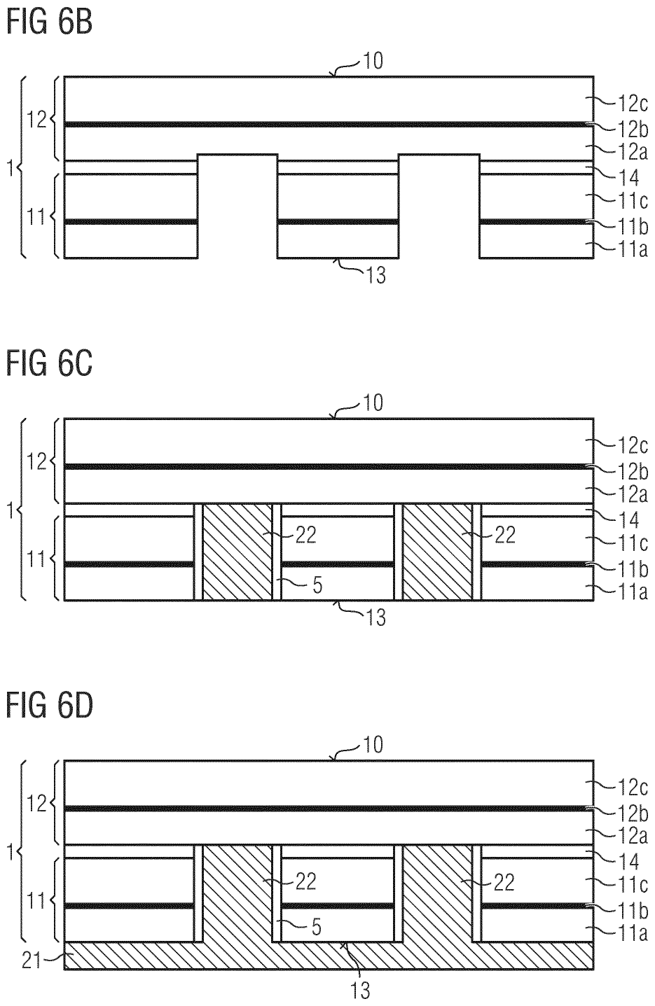

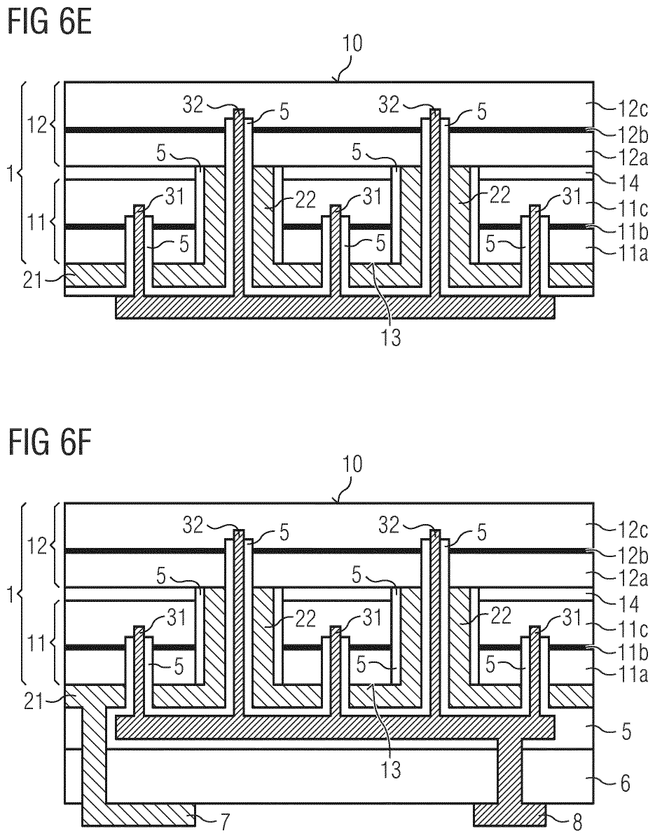

FIGS. 6A to 6F show a first exemplary embodiment of the method for producing an optoelectronic semiconductor chip using a plurality of intermediate positions.

In the first position of FIG. 6A, a first semiconductor layer sequence 11 and a second semiconductor layer sequence 12 are applied to each other by means of a connection layer 14, in particular an adhesive layer 14. This results in a composite 1.

In the second position of FIG. 6B, apertures are made in the first semiconductor layer sequence 11 from a rear face 13 opposite a front face 10 of the composite 1. The apertures completely penetrate the first semiconductor layer sequence 11 as well as the connection layer 14 and extend up to the second semiconductor layer sequence 12. The apertures may form a contiguous grid (see for example FIG. 1B) or they may be apertures spaced apart from each other in pairs which are not connected (see for example FIG. 5B).

FIG. 6C shows a position in which a first contact element 22 is formed in the apertures and is electrically conductively connected to a first layer 12a of the second semiconductor layer sequence 12. In the region of the apertures, the second contact element 22 is electrically insulated from the first semiconductor layer sequence 11 by an insulation material 5.

FIG. 6D shows another position in the method in which a first contact element 21 is formed on the rear face 13. The first contact element 21 is used to contact the first semiconductor layer sequence 11 and is electrically conductively connected to a first layer 11a of the first semiconductor layer sequence 11. In the present case, the first contact element 21 is also electrically conductively connected to the second contact element 22. Other than shown in FIGS. 6C and 6D, the two contact elements 21, 22 could also be formed simultaneously in a common method step.

FIG. 6E shows a position in the method in which first through-connections 31 and second through-connections 32 are formed. The first through-connections 31 extend from the rear face 13 through the first layer 11a and the active layer 11b of the first semiconductor layer sequence 11 and terminate in a second layer 11c of the first semiconductor layer sequence 11. The second through-connections 32 are guided from the rear face 13 completely through the first semiconductor layer sequence 11 and the connection layer 14, cross the first layer 12a and the active layer 12b of the second semiconductor layer sequence 12 and terminate in a second layer 12c of the second semiconductor layer sequence 12. The first and second through-connections 31, 32 may be produced simultaneously or successively.

FIG. 6F shows a position in the method after a carrier 6 has been applied to the rear face 13 of the composite 1. The contact elements 21, 22 and through-connections 31, 32 can be electrically contacted on a side of the carrier 6 facing away from the composite 1 by means of connection areas 7, 8. FIG. 6F also shows an exemplary embodiment of a finished optoelectronic semiconductor chip.

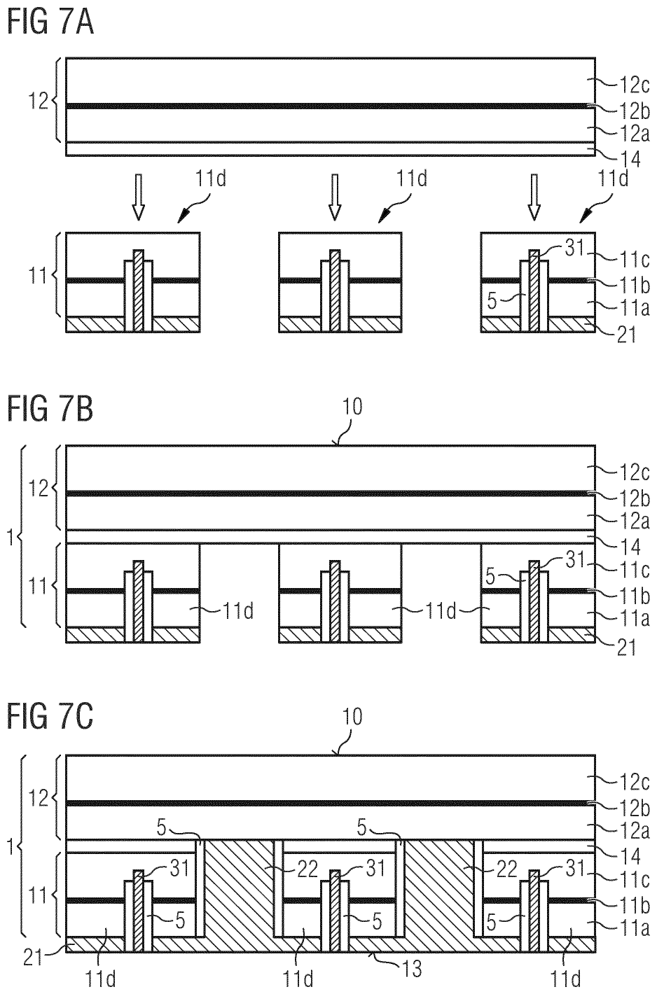

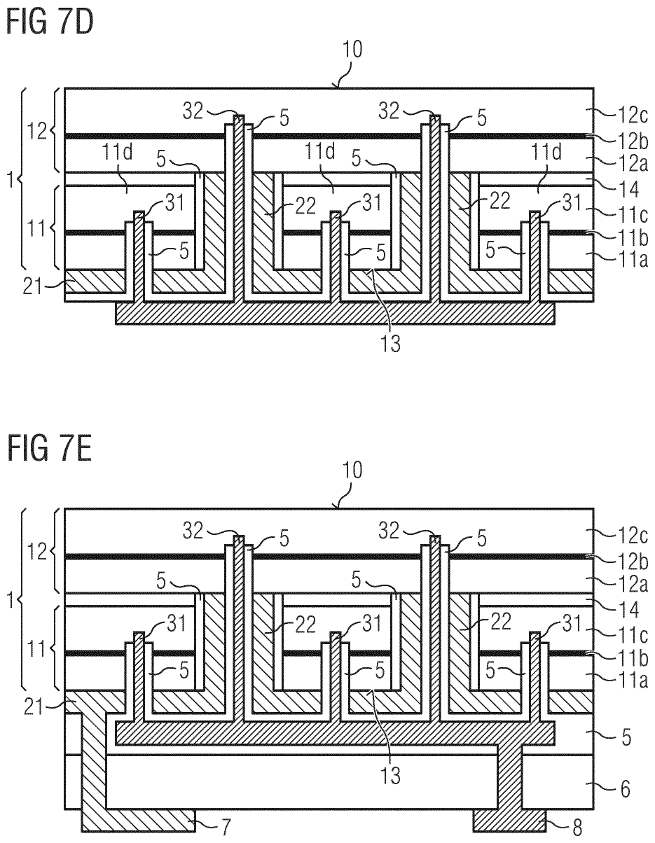

FIGS. 7A to 7E show a second exemplary embodiment of the method using intermediate positions.

In the position shown in FIG. 7A, a second semiconductor layer sequence 12 is provided. A plurality of semiconductor blocks 11d are also provided. In the present case, the semiconductor blocks 11d are provided in the form of micro-LED chips 11d. These micro-LED chips 11d each already include a second through-connection 32 extending through the active layer 11b from one side thereof. On the same side from which the second through-connection 32 extends, a first contact element 21 is also arranged in each case. The micro-LED chips 11d can be contacted via the first contact element 21 and the first through-connection 31.

In FIG. 7A, the semiconductor blocks 11d are arranged on the second semiconductor layer sequence 12 spaced apart from each other by means of a connection layer 14.

FIG. 7B shows a position after the semiconductor blocks 11d have been attached to the second semiconductor layer sequence 12, thereby forming a composite 1. All the semiconductor blocks 11d together form a first semiconductor layer sequence 11 of the composite 1.

In the position shown in FIG. 7C, a second contact element 22 is now formed in the region between the semiconductor blocks 11d. The second contact element 22 extends up to and contacts the second semiconductor layer sequence 12.

FIG. 7D shows a position in the method in which second through-connections 32 are formed which are guided through the second contact element 22 in the region between the semiconductor blocks 11d and subsequently protrude into the second semiconductor layer sequence 12, thereby penetrating the active layer 12b of the second semiconductor layer sequence 12.

FIG. 7E shows another position in which a carrier 6 is applied to the rear face 13 of the composite 1. FIG. 7E also shows an exemplary embodiment of a finished optoelectronic semiconductor chip.

The invention is not limited to the exemplary embodiments by the description based thereon. Rather, the invention encompasses any new feature as well as any combination of features, which in particular includes any combination of features in the patent claims, even if this feature or combination itself is not explicitly stated in the patent claims or embodiments.

This patent application claims the priority of German patent application 102019119891.7, the disclosure content of which is hereby incorporated by reference.

### LIST OF REFERENCE SIGNS

1 composite
5 insulation material
6 carrier
7, 7a, 7b, 8 connection area
10 front face
11 first semiconductor layer sequence
11a first layer of the first semiconductor layer sequence
11b active layer of the first semiconductor layer sequence
11c second layer of the first semiconductor layer sequence
11d semiconductor block second semiconductor layer sequence
12a first layer of the second semiconductor layer sequence
12b active layer of the second semiconductor layer sequence
12c second layer of the second semiconductor layer sequence
13 rear face
21 first contact element
22 second contact element
22a mirror
22b contact pin
31 first through-connection
32 second through-connection

1. An optoelectronic semiconductor chip comprising:
a composite having a front face, a first semiconductor layer sequence and a second semiconductor layer sequence between the front face and the first semiconductor layer sequence;
a first contact element and a second contact element on a side of the composite opposite the front face;
a first through-connection and a second through-connection, each extending into the composite from the side opposite the front face;
wherein:
the first semiconductor layer sequence and the second semiconductor layer sequence each include an active layer for generating or absorbing configured to generate or absorb electromagnetic radiation;
the first contact element and the first through-connection are configured to electrically contact the first semiconductor layer sequence;
the second contact element and the second through-connection are configured to electrically contact the second semiconductor layer sequence;
the first through-connection is guided through the active layer of the first semiconductor layer sequence and the second through-connection is guided through the active layer of the second semiconductor layer sequence; and
the first contact element and the second contact element and the first through-connection and the second through-connection are arranged such that the first semiconductor layer sequence and the second semiconductor layer sequence are electrically connected in parallel, such that charge carriers flow simultaneously through both semiconductor layer sequences in operation; wherein charge carriers flowing through the first semiconductor layer sequence do not enter the second semiconductor layer sequence and vice versa.

2. The semiconductor chip according to claim 1,
wherein the second contact element is guided through the first semiconductor layer sequence up to the second semiconductor layer sequence.

3. The semiconductor chip according to claim 1, wherein
the first contact element and the second contact element are electrically connected to one another and are at the same potential in the intended operation;
the first through-connection and the second through-connection are electrically conductively connected to one another and are at the same potential in the intended operation.

4. The semiconductor chip according to claim 1, wherein
the first contact element and the second contact element are can be contacted independently of each other; and/or
the first through-connection and the second through-connection are contacted independently of each other.

5. The semiconductor chip according to claim 1,
wherein the active layers are configured to emit radiation of different wavelengths.

6. The semiconductor chip according to claim 1,
wherein the second through-connection is guided through the second contact element and is electrically insulated from the second contact element.

7. The semiconductor chip according to claim 1,
wherein:
the second semiconductor layer sequence is formed contiguously;
the first semiconductor layer sequence comprises a plurality of laterally spaced semiconductor blocks;
the semiconductor blocks are distributed along the second semiconductor layer sequence;
the second contact element extends in the region between the semiconductor blocks up to the second semiconductor layer sequence.

8. The semiconductor chip according to claim 1,
wherein the semiconductor chip comprises a plurality of the first through-connection and/or the second through-connection.

9. The semiconductor chip according to claim 7,
wherein each semiconductor block of the first semiconductor layer sequence is uniquely associated with at least one first through-connection.

10. The semiconductor chip according to claim 1,
wherein:
the first semiconductor layer sequence and the second semiconductor layer sequence are each formed contiguously;
the first semiconductor layer sequence and the second semiconductor layer sequence each extend over at least 80% of the lateral extent of the semiconductor chip.

11. A method for producing a semiconductor chip, wherein the method comprises:
forming a composite comprising a first semiconductor layer sequence including an active layer and a second semiconductor layer sequence including an active layer, the second semiconductor layer sequence being arranged between a front face of the composite and the first semiconductor layer sequence,
forming a first contact element,
forming a first through-connection;
wherein:
the first through-connection is guided through the active layer of the first semiconductor layer sequence;
the first contact element and the first through-connection are configured to electrically contact the first semiconductor layer sequence;
forming a second contact element on a side of the composite opposite the front face;
forming a second through-connection;
wherein:
the second contact element and the second through-connection are configured to electrically contact the second semiconductor layer sequence;
the second through-connection is guided through the active layer of the second semiconductor layer sequence;
the first contact element and the second contact element and the first through-connection and the second through-connection are arranged such that the first semiconductor layer sequence and the second semiconductor layer sequence are electrically connected in parallel, such that charge carriers flow simultaneously through both semiconductor layer sequences in operation;
charge carriers flowing through the first semiconductor layer sequence do not enter the second semiconductor layer sequence and vice versa; and
the first semiconductor layer sequence and the second semiconductor layer sequence are electrically insulated from each other.

12. The method according to claim 11, wherein in forming the composition comprises:
providing a plurality of semiconductor blocks each having an active layer;
depositing the semiconductor blocks as separate elements spaced apart from each other on the second semiconductor layer sequence and together form the first semiconductor layer sequence.

13. The method according to claim 12,
wherein forming the first through-connection occurs before forming the composite.

14. The method according to claim 11,
wherein forming the composite comprises depositing the first semiconductor layer sequence as a contiguous semiconductor layer sequence on the second semiconductor layer sequence; and
, further comprising segmenting the first semiconductor layer sequence into a plurality of semiconductor blocks

15. The method according to claim 11, wherein forming the composite comprises bonding the first semiconductor layer sequence and the second semiconductor layer sequence on top of each other.

16. The method according to claim 11, wherein forming the composite comprises gluing the first semiconductor layer sequence and the second semiconductor layer sequence on top of each other.

17. The method according to claim 11, wherein forming the composite comprises epitaxially growing the first semiconductor layer sequence and the second semiconductor layer sequence on top of each other.

18. An optoelectronic semiconductor chip comprising:
a composite having a front face, a first semiconductor layer sequence and a second semiconductor layer sequence between the front face and the first semiconductor layer sequence;
a first contact element and a second contact element on a side of the composite opposite the front face;
a first through-connection and a second through-connection, each extending into the composite from the side opposite the front face;
wherein:
the first and the second semiconductor layer sequence each include an active layer configured to generate or absorb electromagnetic radiation;
the first contact element and the first through-connection are configured to electrically contact the first semiconductor layer sequence;
the second contact element and the second through-connection are configured to electrically contact the second semiconductor layer sequence;
the first through-connection is guided through the active layer of the first semiconductor layer sequence and the second through-connection is guided through the active layer of the second semiconductor layer sequence;
the first contact element and the second contact element and the first through-connection and the second through-connection are arranged such that the first semiconductor layer sequence and the second semiconductor layer sequence are electrically connected in parallel, such that charge carriers flow simultaneously through both semiconductor layer sequences in operation,
charge carriers flowing through the first semiconductor layer sequence do not enter the second semiconductor layer sequence and vice versa; and
the first semiconductor layer sequence and the second semiconductor layer sequence are electrically insulated from each other.
